(19) United States
(12) Patent Application Publication
(10) Pub. No.: US 2009/0176322 A1
(43) Pub. Date: Jul. 9, 2009

(54) METHOD FOR FABRICATING AN INK JETTING DEVICE

(76) Inventors: Burton L. Joyner, II, Lexington, KY (US); Zachary J. Reitmeier, Lexington, NY (US)

Correspondence Address: LEXMARK INTERNATIONAL, INC.;INTELLECTUAL PROPERTY LAW DEPARTMENT, 740 WEST NEW CIRCLE ROAD, BLDG. 082-1, LEXINGTON, KY, 40550-0999, US

(21) Appl. No.: 11/969,234

(22) Filed: Jan. 4, 2008

(51) Int. Cl. H01L 21/00

(52) U.S. Cl. 438/21; 257/E21.001

(57) ABSTRACT

A method for forming an ink jetting device includes providing a silicon chip including a silicon substrate having a first surface and a second surface opposite to the first surface, the first surface having formed thereon a plurality of electrical heater elements and a silicon oxide ink ejection chamber layer configured to define a plurality of ink ejection chambers; providing a silicon nozzle plate having a silicon nozzle layer having a third surface and a fourth surface opposite to the third surface, the fourth surface having formed thereon a silicon oxide layer; aligning the silicon nozzle plate with the silicon chip; fusion bonding the silicon oxide layer of the silicon nozzle plate to the silicon oxide ink ejection chamber layer of the silicon chip; and forming a plurality of nozzle holes through the silicon nozzle plate respectively located over the plurality of electrical heater elements.

### BACKGROUND OF THE INVENTION

1. Field of the Invention

The present invention relates to a printhead, and, more particularly, to a method for fabricating an ink jetting device.

2. Description of the Related Art

A typical ink jet printhead includes a silicon chip to which a nozzle plate fabricated from a polymer material is attached. Also, some ink jet printheads include a silicon nozzle plate. However, typical methods of bonding the silicon nozzle plate to the silicon chip are anodic in nature, which is not compatible with some devices, such as for example, complementary metal-oxide-semiconductor (CMOS) devices.

### SUMMARY OF THE INVENTION

The present invention provides a method for fabricating an ink jetting device that includes a silicon nozzle plate joined to a silicon chip, which may include, for example, CMOS components.

The terms “first” and “second” preceding an element name, e.g., first surface, second surface, etc., are used for identification purposes to distinguish between similar or related elements, results or concepts, and are not intended to necessarily imply order, nor are the terms “first” and “second” intended to preclude the inclusion of additional similar or related elements, results or concepts, unless otherwise indicated.

The invention, in one form thereof, is directed to a method for forming an ink jetting device. The method includes: providing a silicon chip including a silicon substrate having a first surface and a second surface opposite to the first surface, the first surface having formed thereon a plurality of electrical heater elements and a silicon oxide ink ejection chamber layer configured to define a plurality of ink ejection chambers, where each ink ejection chamber of the plurality of ink ejection chambers is associated with at least one respective electrical heater element of the plurality of electrical heater elements; providing a silicon nozzle plate having a silicon nozzle layer having a third surface and a fourth surface opposite to the third surface, the fourth surface having formed thereon a silicon oxide layer; aligning the silicon nozzle plate with the silicon chip; fusion bonding the silicon oxide layer of the silicon nozzle plate to the silicon oxide ink ejection chamber layer of the silicon chip; and forming a plurality of nozzle holes through the silicon nozzle plate respectively located over the plurality of electrical heater elements.

The invention in another form thereof, is directed to a method for forming an ink jetting device. The method includes: providing a silicon chip including a silicon substrate having a first surface and a second surface opposite to the first surface, the first surface having formed thereon a plurality of electrical heater elements, a plurality of CMOS components, and a silicon oxide ink ejection chamber layer configured to define a plurality of ink ejection chambers, where each ink ejection chamber of the plurality of ink ejection chambers is associated with at least one respective electrical heater element of the plurality of electrical heater elements, and having a central ink via formed through the second surface that is in fluid communication with the plurality of ink ejection chambers; providing a silicon nozzle plate having a silicon nozzle layer having a third surface and a fourth surface opposite to the third surface, the fourth surface having formed thereon a silicon oxide layer; aligning the silicon nozzle plate with the silicon chip; fusion bonding the silicon oxide layer of the nozzle plate to the silicon oxide ink ejection chamber layer of the silicon chip; applying a mask layer over the third surface of the silicon nozzle layer; patterning the mask layer to define locations for a plurality of nozzle holes respectively located over the plurality of electrical heater elements; and removing portions of the silicon nozzle layer and the silicon oxide layer of the silicon nozzle plate to form the plurality of nozzle holes through the silicon nozzle plate.

The invention, in another form thereof, is directed to a method for forming an ink jetting device. The method includes: providing a silicon chip including a silicon substrate having a first surface and a second surface opposite to the first surface, the first surface having formed thereon a plurality of electrical heater elements and a silicon oxide ink ejection chamber layer configured to define a plurality of ink ejection chambers, where each ink ejection chamber of the plurality of ink ejection chambers is associated with at least one respective electrical heater element of the plurality of electrical heater elements; thinning a silicon nozzle plate having a silicon nozzle layer having a third surface and a fourth surface opposite to the third surface to a predefined thickness in a range of about 0.01 to about 50 microns, the fourth surface having formed thereon a silicon oxide layer; aligning the silicon nozzle plate with the silicon chip; fusion bonding the silicon oxide layer of the nozzle plate to the silicon oxide ink ejection chamber layer of the silicon chip; and forming a plurality of nozzle holes through the silicon nozzle plate respectively located over the plurality of electrical heater elements.

### BRIEF DESCRIPTION OF THE DRAWINGS

The above-mentioned and other features and advantages of this invention, and the manner of attaining them, will become more apparent and the invention will be better understood by reference to the following description of an embodiment of the invention taken in conjunction with the accompanying drawings, wherein:

FIG. 1 is a diagrammatic illustration of a cross section view of a silicon chip having electrical components and a silicon oxide ink ejection chamber layer formed thereon.

FIG. 2 is a diagrammatic illustration of a cross section view of a silicon nozzle plate having a silicon nozzle layer and a silicon oxide layer.

FIG. 3 is a diagrammatic illustration of a cross section view of the silicon nozzle plate of FIG. 2 fused to the silicon chip of FIG. 1.

FIG. 4 is a diagrammatic illustration of a cross section view of a patterned mask layer formed on the silicon nozzle layer of the silicon nozzle plate to define the location of a plurality of nozzle holes.

FIG. 5 is a diagrammatic illustration of a cross section view of the etching of the nozzle holes through the silicon nozzle layer of the silicon nozzle plate past the patterned mask layer.

FIG. 6 is diagrammatic illustration of a top view of a portion of a completed ink jetting device, following the removal of the mask layer and a portion of the silicon oxide layer of the silicon nozzle plate corresponding to the locations of the plurality of nozzle holes.

FIG. 7 is a cross section of the diagrammatic illustration of FIG. 6 taken along line 7-7 of FIG. 6.

FIG. 8 is a flowchart of a method for forming an ink jetting device in accordance with an aspect of the present invention.

FIG. 9 is a more detailed flowchart of an exemplary method for performing the act of forming a plurality of nozzle holes through the silicon nozzle plate in the method of FIG. 8.

Corresponding reference characters indicate corresponding parts throughout the several views. The exemplifications set out herein illustrate one embodiment of the invention, in one form, and such exemplifications are not to be construed as limiting the scope of the invention in any manner.

### DETAILED DESCRIPTION OF THE INVENTION

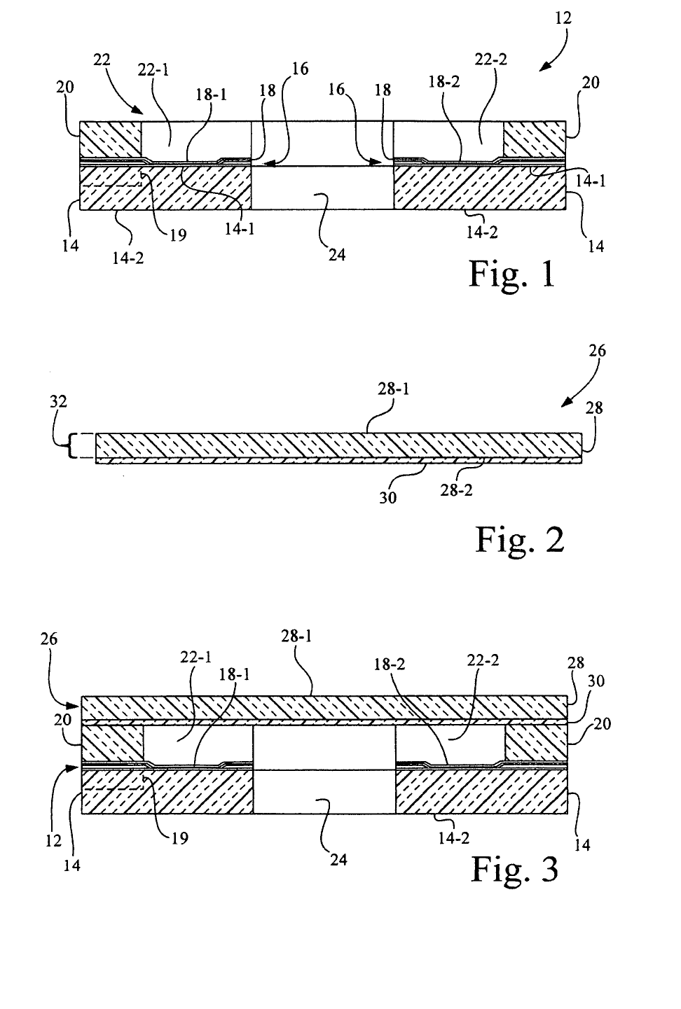

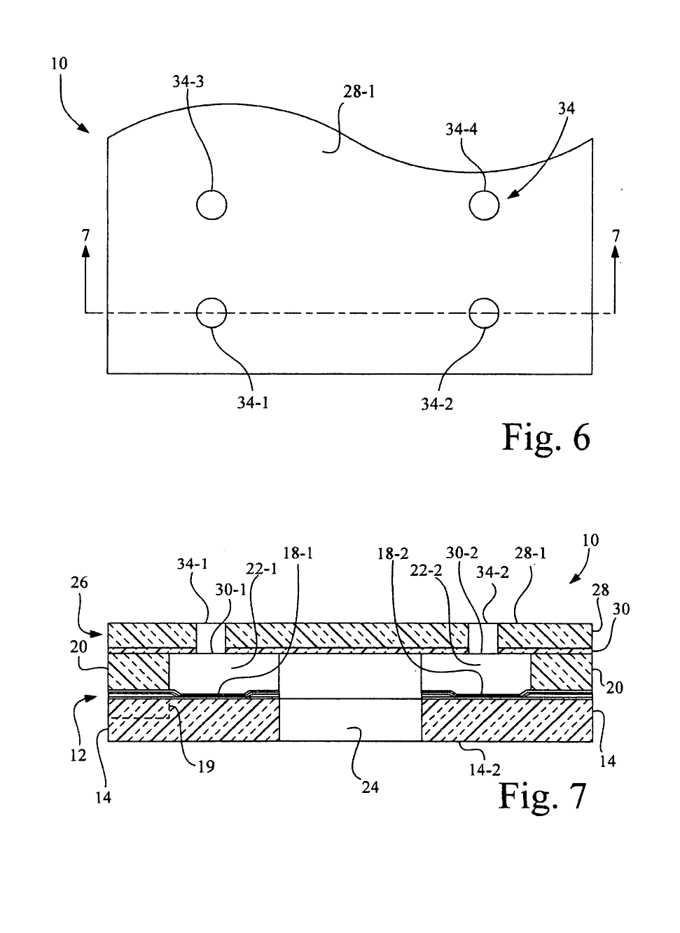

Referring now to the drawings and particularly to FIGS. 1-7, there is shown various fabrication stages associated with a method for fabricating an ink jetting device 10 (see FIGS. 6 and 7) in accordance with an aspect of the present invention. Those skilled in the art will recognize that the structures shown in FIGS. 1-7 are exaggerated in size and shape to more clearly show fabrication aspects of the present invention. The section views shown in FIGS. 1-5 illustrate the fabrication process up to the completion of ink jetting device 10 illustrated in FIGS. 6 and 7, taken along a line corresponding in location to line 7-7 of FIG. 6

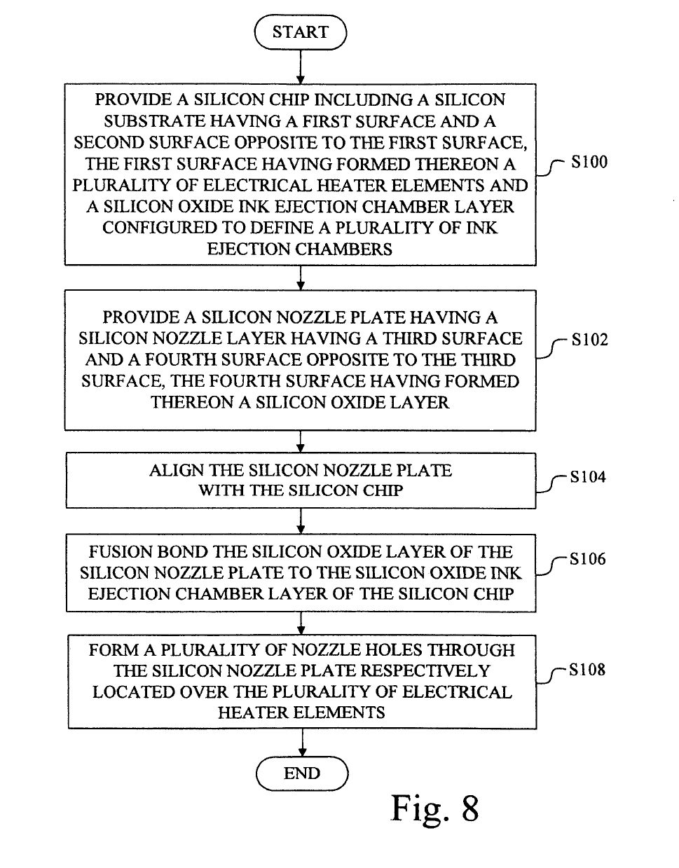

The various acts associated with the method for fabricating an ink jetting device 10 in accordance with the present invention are summarized in the flowchart of FIG. 8.

At act S100, with reference to FIG. 1, there is provided a silicon chip 12 including a silicon substrate 14, such as portion of a first silicon wafer, having a first surface 14-1 and a second surface 14-2 opposite to first surface 14-1, i.e., is on an opposite side of silicon substrate 14 from first surface 14-1. First surface 14-1 has formed thereon a plurality of electrical components 16, including a plurality of electrical heater elements 18 and a plurality of CMOS circuit components 19 (schematically illustrated in FIG. 1 as a dashed rectangular box). In the present example only two electrical heater elements 18-1, 18-2 is shown, but it is to be understood that the actual number of electrical heater elements 18 may be in the hundreds or thousands. CMOS circuits 19 may be configured, for example, to provide addressing of each of the plurality of electrical heater elements 18, and may further include registers/memory for storing print data, printhead identification information, etc.

First surface 14-1 also has formed thereon a silicon oxide ink ejection chamber layer 20 configured to define a plurality of ink ejection chambers 22, including ink ejection chambers 22-1 and 22-2 as shown in FIG. 1. Each ink ejection chamber of the plurality of ink ejection chambers 22 is associated with at least one respective electrical heater element of the plurality of electrical heater elements 18.

A central ink via 24, i.e., an ink carrying passageway, is formed through the second surface 14-2 of silicon substrate 14, and is configured to be in fluid communication with the plurality of ink ejection chambers 22.

At act S102, referring to FIG. 2, there is provided a silicon nozzle plate 26, such as a portion of a second silicon wafer, having a silicon nozzle layer 28 having a third surface 28-1 and a fourth surface 28-2 opposite to the third surface 28-1, i.e., is on an opposite side of silicon nozzle layer 28 from third surface 28-1. Formed on fourth surface 28-2 of silicon nozzle layer 28 is a silicon oxide layer 30.

In accordance to one aspect of the present invention, silicon nozzle layer 28 is thinned to a thickness 32 in a range of about 0.01 to about 50 microns. In one embodiment, for example, silicon nozzle layer 28 is thinned to a thickness 32 of about 25 microns. In the present embodiment, the thinning of silicon nozzle layer 28 is performed prior to the fusion bonding of silicon nozzle plate 26 to silicon chip 12 at act S106 below. However, it is contemplated that the thinning of silicon nozzle layer 28 may be performed after the fusion bonding of silicon nozzle plate 26 to silicon chip 12, as late as a final act in fabricating ink jetting device 10, if desired. Thinning may be performed, for example, by using a chemical mechanical polishing process or a machining process such as backgrinding.

At act S104, referring to FIG. 3, silicon nozzle plate 26 is aligned with silicon chip 12. In one embodiment, for example, alignment is performed on the wafer level, not chip by chip. In other words, silicon chip 12 is a portion of a first silicon wafer and silicon nozzle plate 26 is a portion of a second silicon wafer. The wafer having silicon nozzle plate 26 may be optically transparent so optical technology may be used for alignment. Additionally, if the top wafer thickness is out of the optical transparency range, the alignment of the wafers may be carried out through silicon using an infrared (IR) camera and fiducials on the silicon wafer having silicon chip 12. Alternatively, although less preferred, it is possible to perform alignment on a chip by chip level.

At act S106, referring to FIG. 3, silicon oxide layer 30 of silicon nozzle plate 26 is fusion bonded to silicon oxide ink ejection chamber layer 20 of silicon chip 12.

Fusion bonding is a process by which silicon to silicon bonds, silicon oxide to silicon bonds, or silicon oxide to silicon oxide bonds, may be made. A typical fusion bonding process would begin by treating the surfaces to be bonded to insure cleanliness. Once cleanliness is insured, the two surfaces to be bonded are brought together and aligned. This may be accomplished, for example, through a silicon wafer by an infrared (IR) camera and fiducial. Once the alignment is carried out, the surfaced are put together and a pre-bond is made at room temperature using a slight pressure. Next, the pre-bond is inspected for voids. If voids are present, the surfaces are re-bonded by another pressure wave. After pre-bonding the bond strength is such that the resulting device may be handled in subsequent fabrication acts. The use of pressure bonding devices alleviates the need for atomic level planarity of the surfaces to be bonded. After the pressure bonding, a low temperature anneal completes the fusion bonding process.

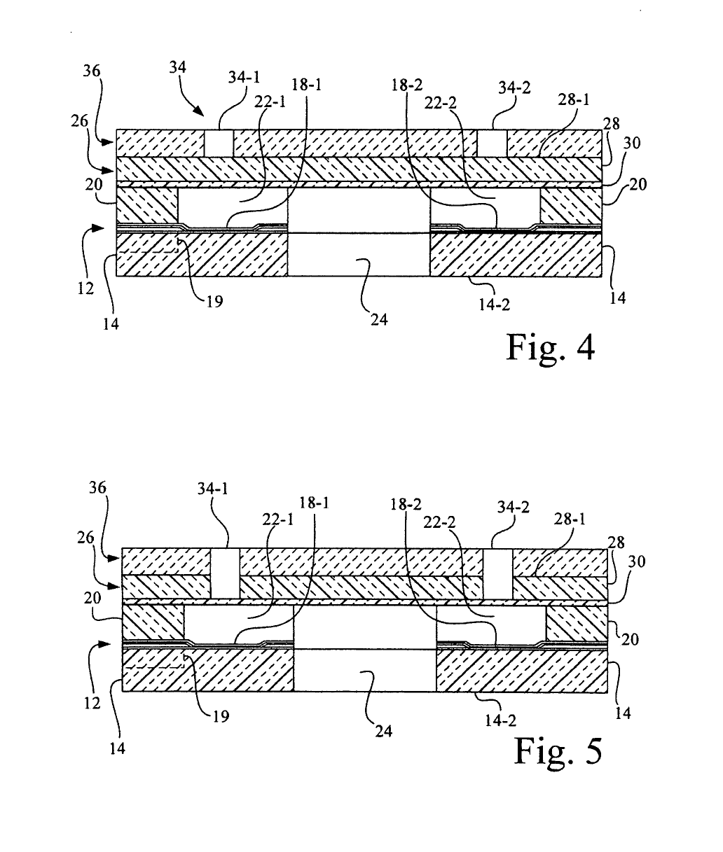

At act S108, referring to FIGS. 4-7, a plurality of nozzle holes 34, e.g., nozzle holes 34-1, 34-2, 34-3 and 34-4, are formed through silicon nozzle plate 26 and are respectively located over the plurality of electrical heater elements 18. In one preferred embodiment, the act of forming the plurality of nozzle holes 34 through silicon nozzle plate 26 of act S108 is performed following the act of fusion bonding of silicon nozzle plate 26 to silicon chip 12 so as to increase the accuracy of alignment of the plurality of nozzle holes 34 with respective ink ejection chambers 22. Alternatively, although less preferred, the plurality of nozzle holes 34 may be performed prior to act S104 and/or act S106.

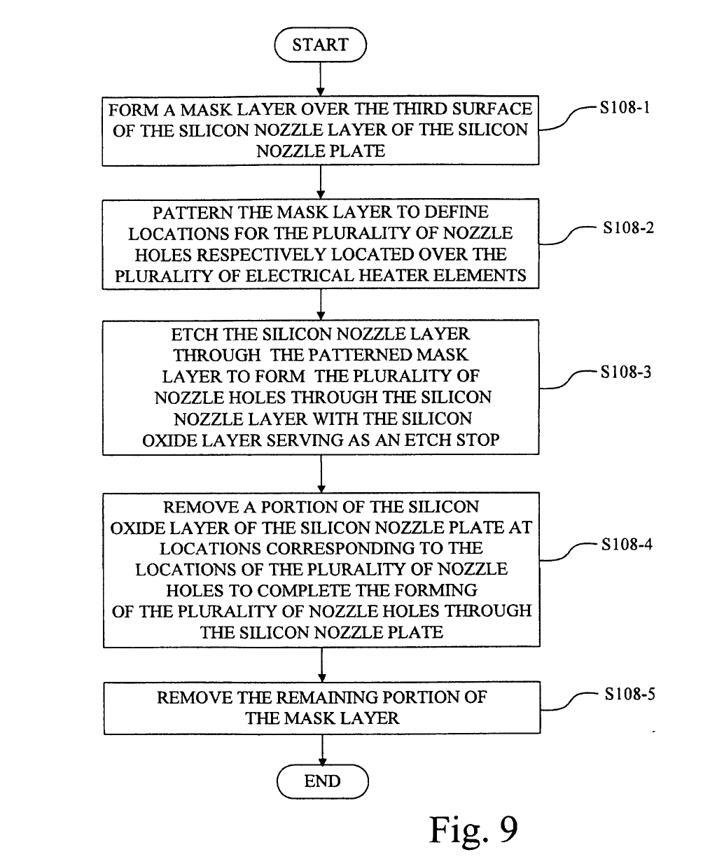

In the present embodiment, act S108 may be implemented as follows, with reference to the flowchart of FIG. 9.

At act S108-1, referring to FIG. 4, a mask layer 36 is formed over third surface 28-1 of silicon nozzle layer 28 of silicon nozzle plate 26.

At act S108-2, mask layer 36 is then patterned, as illustrated in FIG. 4, to define locations for the plurality of nozzle holes 34 respectively located over the plurality of electrical heater elements 18, e.g., the nozzle holes 34-1, 34-2 located over ink ejection chambers 22-1 and 22-2, and more particularly, over electrical heater elements 18-1, 18-2, respectively. Mask layer 36 may be formed, for example, using a photoresist material, as is known in the art.

At act S108-3, referring to FIG. 5, silicon nozzle layer 28 is etched through the patterned mask layer 36 to form the plurality of nozzle holes 34 through silicon nozzle layer 28, with silicon oxide layer 30 serving as an etch stop. The etching may be performed, for example, by a deep reactive ion etch (DRIE) process.

At act S1084, as best shown in FIG. 7, a portion of silicon oxide layer 30 of silicon nozzle plate 26 (e.g., portions 30-1, 30-2) is removed at locations corresponding to the locations of the plurality of nozzle holes 34 to complete the forming of the plurality of nozzle holes 34 through silicon nozzle plate 26, as illustrated in FIGS. 6 and 7. Act S1084 may be performed using, for example, hydrofluoric acid vapor etching (HFVE).

At act S108-S, the remaining portion of mask layer 36 is removed, as illustrated in FIGS. 6 and 7, thus completing the fabrication of ink jetting device 10. Mask layer 36 may be removed, for example, by a solvent or by etching, depending on the type of material used for mask layer 36.

While this invention has been described with respect to embodiments of the invention, the present invention may be further modified within the spirit and scope of this disclosure. This application is therefore intended to cover any variations, uses, or adaptations of the invention using its general principles. Further, this application is intended to cover such departures from the present disclosure as come within known or customary practice in the art to which this invention pertains and which fall within the limits of the appended claims.

What is claimed is:

1. A method for forming an ink jetting device from a silicon chip including a silicon substrate having a first surface and a second surface opposite to said first surface, said first surface having formed thereon a plurality of electrical heater elements and a silicon oxide ink ejection chamber layer configured to define a plurality of ink ejection chambers, where each ink ejection chamber of said plurality of ink ejection chambers is associated with at least one respective electrical heater element of said plurality of electrical heater elements; and from a silicon chip including a silicon substrate having a first surface and a second surface opposite to said first surface, said first surface having formed thereon a plurality of electrical heater elements and a silicon oxide ink ejection chamber layer configured to define a plurality of ink ejection chambers, where each ink ejection chamber of said plurality of ink ejection chambers is associated with at least one respective electrical heater element of said plurality of electrical heater elements, the method comprising:
aligning said silicon nozzle plate with said silicon chip;
fusion bonding said silicon oxide layer of said silicon nozzle plate to said silicon oxide ink ejection chamber layer of said silicon chip; and
forming a plurality of nozzle holes through said silicon nozzle plate respectively located over said plurality of electrical heater elements.

2. The method of claim 1, wherein said forming said plurality of nozzle holes through said silicon nozzle plate is performed following said fusion bonding.

3. The method of claim 2, wherein said forming said plurality of nozzle holes includes:
applying a mask layer over said third surface of said silicon nozzle layer;
patterning said mask layer to define locations for said plurality of nozzle holes respectively located over said plurality of electrical heater elements;
etching said silicon nozzle layer through the patterned mask layer to form said plurality of nozzle holes through said silicon nozzle layer; and
removing a portion of said silicon oxide layer of said silicon nozzle plate corresponding to said locations of said plurality of nozzle holes to complete forming of said plurality of nozzle holes through said silicon nozzle plate.

4. The method of claim 1, further comprising thinning said silicon nozzle layer to a thickness in a range of about 0.01 to about 50 microns.

5. The method of claim 4, wherein said silicon nozzle layer is thinned to a thickness of about 25 microns.

6. The method of claim 4, wherein said thinning of said silicon nozzle layer is performed prior to said fusion bonding.

7. The method of claim 1, further comprising a plurality of CMOS components formed on said silicon chip.

8. A method for forming an ink jetting device, comprising:
providing a silicon chip including a silicon substrate having a first surface and a second surface opposite to said first surface, said first surface having formed thereon a plurality of electrical heater elements, a plurality of CMOS components, and a si licon oxide ink ejection chamber layer configured to define a plurality of ink ejection chambers, where each ink ejection chamber of said plurality of ink ejection chambers is associated with at least one respective electrical heater element of said plurality of electrical heater elements, and having a central ink via formed through said second surface that is in fluid communication with said plurality of ink ejection chambers;
providing a silicon nozzle plate having a silicon nozzle layer having a third surface and a fourth surface opposite to said third surface, said fourth surface having formed thereon a silicon oxide layer;
aligning said silicon nozzle plate with said silicon chip;
fusion bonding said silicon oxide layer of said nozzle plate to said silicon oxide ink ejection chamber layer of said silicon chip;
applying a mask layer over said third surface of said silicon nozzle layer;
patterning said mask layer to define locations for a plurality of nozzle holes respectively located over said plurality of electrical heater elements; and
removing portions of said silicon nozzle layer and said silicon oxide layer of said silicon nozzle plate to form said plurality of nozzle holes through said silicon nozzle plate.

9. The method of claim 8, further comprising thinning said silicon nozzle layer to a thickness in a range of about 0.01 to about 50 microns.

10. The method of claim 9, wherein said silicon nozzle layer is thinned to a thickness of about 25 microns.

11. The method of claim 9, wherein said thinning of said silicon nozzle layer is performed prior to said fusion bonding.

12. A method for forming an ink jetting device from a silicon chip including a silicon substrate having a first surface and a second surface opposite to said first surface, said first surface having formed thereon a plurality of electrical heater elements and a silicon oxide ink ejection chamber layer configured to define a plurality of ink ejection chambers, where each ink ejection chamber of said plurality of ink ejection chambers is associated with at least one respective electrical heater element of said plurality of electrical heater elements, the method comprising:
thinning a silicon nozzle plate having a silicon nozzle layer having a third surface and a fourth surface opposite to said third surface to a predefined thickness in a range of about 0.01 to about 50 microns, said fourth surface having formed thereon a silicon oxide layer;
aligning said silicon nozzle plate with said silicon chip;
fusion bonding said silicon oxide layer of said nozzle plate to said silicon oxide ink ejection chamber layer of said silicon chip; and
forming a plurality of nozzle holes through said silicon nozzle plate respectively located over said plurality of electrical heater elements.

13. The method of claim 12, wherein said forming said plurality of nozzle holes through said silicon nozzle plate is performed following said fusion bonding.

14. The method of claim 13, wherein said forming said plurality of nozzle holes includes:
applying a mask layer over said third surface of said silicon nozzle plate;
patterning said mask layer to define locations for said plurality of nozzle holes respectively located over said plurality of electrical heater elements;
etching said silicon nozzle layer through the patterned mask layer to form said plurality of nozzle holes through said silicon nozzle layer; and
removing a portion of said silicon oxide layer of said silicon nozzle plate corresponding to said locations of said plurality of nozzle holes to complete forming of said plurality of nozzle holes through said silicon nozzle plate.

15. The method of claim 12, wherein said silicon nozzle layer is thinned to a thickness of about 25 microns.

16. The method of claim 12, wherein said thinning of said silicon nozzle layer is performed prior to said fusion bonding.

17. The method of claim 12, further comprising a plurality of CMOS components formed on said silicon chip.
